(19) United States
(12) Patent Application Publication
(10) Pub. No.: US 2026/0301797 A1
(43) Pub. Date: Oct. 1, 2026

(54) SENSE CIRCUIT FOR MULTI-TRANSISTOR CAPACITORLESS DYNAMIC RANDOM ACCESS MEMORY (DRAM) CELL

(71) Applicant: Rambus Inc., SAN JOSE, CA (US)

(72) Inventor: Thomas Vogelsang, Jericho, VT (US)

(21) Appl. No.: 19/477,416

(22) PCT Filed: May 2, 2024
(86) PCT No.: PCT/US2024/027390

§ 371 Date: Oct. 21, 2025

Related U.S. Application Data
(60) Provisional application No. 63/463,492, filed on May 2, 2023.

(51) Int. Cl. G11C 11/4091; G11C 11/4096; H10B 12/00

(52) U.S. Cl. CPC G11C 11/4091; G11C 11/4096; H10B 12/20; H10B 12/50

(57) ABSTRACT

A memory device includes an array of storage cells. Each storage cell is coupled to one of multiple bitlines and one of multiple wordlines. Reference cell circuitry includes reference cells, with each reference cell being coupled to a separate one of the multiple bitlines. For a given storage cell activated during a read operation by a given wordline and bitline, a corresponding reference cell is coupled to the given bitline and cooperates with the given storage cell to form a voltage divider circuit having a sense node. Sense amplifier circuitry, during the read operation, senses a stored state of the given storage cell based on a voltage developed by the voltage divider circuit at the sense node.

### TECHNICAL FIELD

The disclosure herein relates to memory systems, memory controllers, memory devices, and associated methods.

### BRIEF DESCRIPTION OF THE DRAWINGS

Embodiments of the disclosure are illustrated by way of example, and not by way of limitation, in the figures of the accompanying drawings and in which like reference numerals refer to similar elements and in which:

FIG. 1 illustrates one embodiment of a memory system that employs a memory controller, and at least one memory device.

FIG. 2A illustrates one embodiment of a capacitorless dynamic random access memory (DRAM) cell utilized in the memory device shown in FIG. 1.

FIG. 2B illustrates an equivalent circuit diagram corresponding to the capacitorless DRAM cell of FIG. 2A.

FIG. 3 illustrates one embodiment of a sense circuit for sensing a state of a capacitorless DRAM cell such as that shown in FIG. 2A.

FIG. 4 illustrates a voltage divider that corresponds to a portion of the sense circuit of FIG. 3.

FIG. 5 illustrates relative timings for various memory operations performed by the sense circuit of FIG. 3 while in operation.

FIG. 6 illustrates one embodiment of a method of operating the sense circuit of FIG. 3.

### DETAILED DESCRIPTION

Memory devices, modules, controllers, systems and associated methods are disclosed. In one embodiment, a memory device is disclosed. The memory device includes an array of storage cells. Each storage cell is coupled to one of multiple bitlines and one of multiple wordlines. Reference cell circuitry includes reference cells, with each reference cell being coupled to a separate one of the multiple bitlines. For a given storage cell activated during a read operation by a given wordline and bitline, a corresponding reference cell is coupled to the given bitline and cooperates with the given storage cell to form a voltage divider circuit having a sense node. Sense amplifier circuitry, during the read operation, senses a stored state of the given storage cell based on a voltage developed by the voltage divider circuit at the sense node. Some embodiments described herein may employ an array of capacitorless dynamic random access memory (DRAM) storage cells as the array of storage cells. In some embodiments, the array of storage cells comprises an array of capacitorless dynamic random access memory (DRAM) storage cells, where each capacitorless DRAM storage cell includes a first pair of series-coupled transistors that are activated by the given one of the multiple wordlines and the given one of the multiple bitlines. By employing reference cell circuitry to cooperate with the storage cells to form a voltage divider during a read operation, the sense amplifier circuitry may sense a stored state of the storage cells based on a voltage parameter rather than a charge parameter, enabling the ability of the sensing circuit to sense storage states from capacitorless DRAM storage cells.

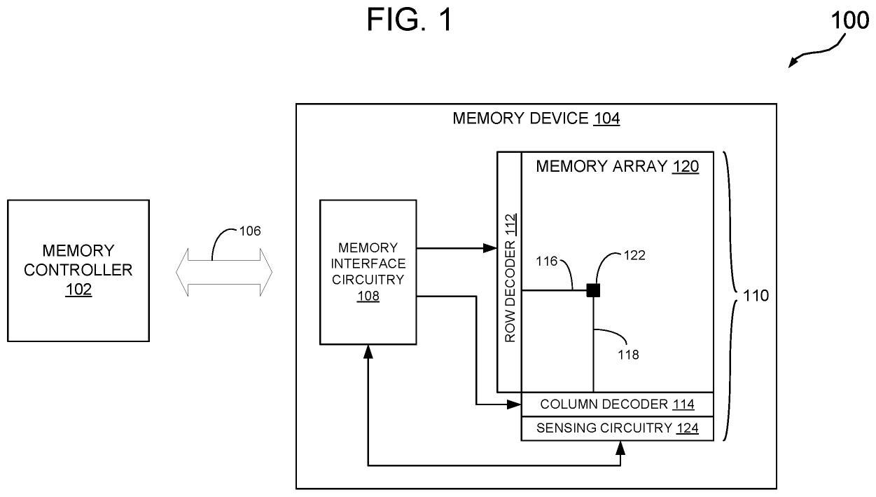

Referring now to FIG. 1, a memory system, generally designated 100, is shown that includes a memory controller 102 coupled to one or more memory devices 104 via signaling media 106. For one embodiment, the memory controller 102 is a dynamic random access memory (DRAM) controller, with the memory device 104 realized as a DRAM memory device. In some embodiments, the memory controller 102 and memory device 104 may be embodied as integrated circuits, or chips. Other embodiments may employ the memory controller 102 as a circuit in a host central processing unit (CPU) (not shown). Specific embodiments for the DRAM memory controller 102 and memory 104 may be compliant with various DRAM standards, including double data rate (DDR) variants, low power (LPDDR) versions, high bandwidth (HBM), and graphics (GDDR) types. Other embodiments may include multi-chip modules that, for example, employ stacked memory die, or stacked packages. Such embodiments may be used with the memory devices 104. Additional embodiments may stack memory die and logic die together in a common package, or in separate packages stacked upon each other. Yet other embodiments may employ multiple memory devices on a substrate (not shown) in a memory module configuration for high-capacity applications.

Further referring to FIG. 1, for one embodiment, each memory device 104 includes memory interface circuitry 108 for handling communications between the memory controller 102 and memory core circuitry 110 of the memory device 104. The memory core circuitry 110 generally includes row decoder circuitry 112 and column decoder circuitry 114 that activate a given wordline 116 and bitline 118, respectively, in a memory array 120 in response to receiving address information from the memory interface circuitry 108. The activated wordline 116 and bitline 118 cooperate to activate access to a given storage cell 122. For one embodiment, explained more fully below, the storage cell 122 may take the form of a capacitorless DRAM storage cell that is more scalable to smaller process nodes than capacitor-based DRAM cells. Sensing circuitry 124 employs a unique voltage-based sensing scheme to determine the state of the capacitorless DRAM cell while preserving many of the features typically associated with legacy sensing schemes. As a result, for some embodiments, the use of capacitorless DRAM cells in the memory array 120 with the improved sensing circuitry 124 may allow for greatly increased DRAM cell density within the memory array 120 with minimal changes needed in the rest of the memory system 100.

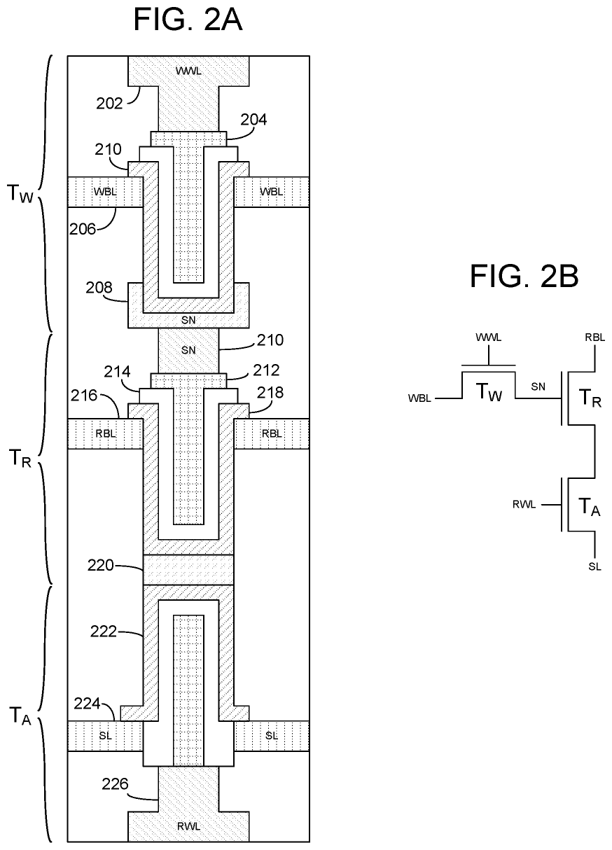

FIG. 2A illustrates one embodiment of a capacitorless DRAM cell architecture. In an effort to realize transistors with extremely low leakage, one process technology embodiment employs wide bandgap oxide semiconductors such as Indium Gallium Zinc Oxide (IGZO). For one embodiment, the capacitorless DRAM cell architecture takes the form of a multi-transistor zero-capacitor structure such as a two-transistor zero-capacitor (2T0C) or three-transistor zero-capacitor (3T0C) shown in FIG. 2A. While both cell structures provide a write transistor T_{W} that is stacked with a read transistor T_{R}, a 3T0C cell incorporates an additional access transistor T_{A} that is stacked with the other two transistors T_{W} and T_{R}, albeit in a reverse orientation such that it is disposed in series with the read transistor T_{R}. The additional access transistor T_{A} assists in eliminating transient currents that may be inherent in a T20C cell structure.

Further referring to FIG. 2A, the write transistor T_{W} of the 3T0C cell includes a gate contact 202 that is vertically stacked with a gate conductor 204. A source contact 206 and a drain contact 208 couple to a channel 210 that forms a conductive path when biased by a write word line (WWL) voltage applied to the gate contact 202 and a write bit line (WBL) voltage applied to the source contact 206. The drain contact 208 of the write transistor T_{W} is stacked on a second gate contact 210 of the read transistor T_{R}. The second gate contact 210 vertically sits atop a second gate conductor 212. The drain contact 208 of the write transistor T_{W} and the second gate conductor 212 cooperate with the second gate contact 210 to form a storage node SN. An insulator material at 214 electrically isolates the storage node SN from a second source contact 216 and a second channel 218 associated with the read transistor T_{R}.

With continued reference to FIG. 2A, the access transistor T_{A} is formed similarly to the write transistor T_{W} and the read transistor T_{R}, but is stacked “bottoms-up” with the read transistor T_{R} such that the two transistors form a series configuration. The access transistor T_{A} includes a third source contact 220 that also forms a drain contact for the read transistor T_{R}. A third channel 222 couples the third source contact to a third drain contact 224 when a read word line (RWL) control signal is applied to a third gate contact 226.

FIG. 2B schematically illustrates the structure of the capacitorless DRAM cell of FIG. 2A for ease in describing write and read operations involving the cell. During a write operation, a write word line WWL control signal is applied to the gate of the write transistor T_{W} to activate the write transistor T_{W} and bring one of two amounts of charge (corresponding to a logic “0” or a logic “1”) to the storage node SN. The write word line WWL control signal is turned off once the charge is brought to the storage node SN. Once brought in to the storage node SN, the charge remains stored on the node, representing a stored “1” or “0” state. To read the state of the storage node SN, a current path needs to be formed between the read transistor source contact, which is selectively coupled to the read bit line (RBL) voltage, and the drain contact of the access transistor T_{A}, which is selectively coupled to the source line (SL) voltage. If the charge stored on the storage node is at a high level, corresponding to a logic “1”, then a large current flows through the read transistor T_{R} and the access transistor T_{A}. Conversely, if the charge stored on the storage node SN is at a low level, corresponding to a logic “0”, then the read transistor T_{R} remains in an off state, with very little current flow through the series configuration of T_{R} and T_{A}. The state of the storage node may thus be determined by detecting the current flow through the read transistor T_{R} and the access transistor T_{A}.

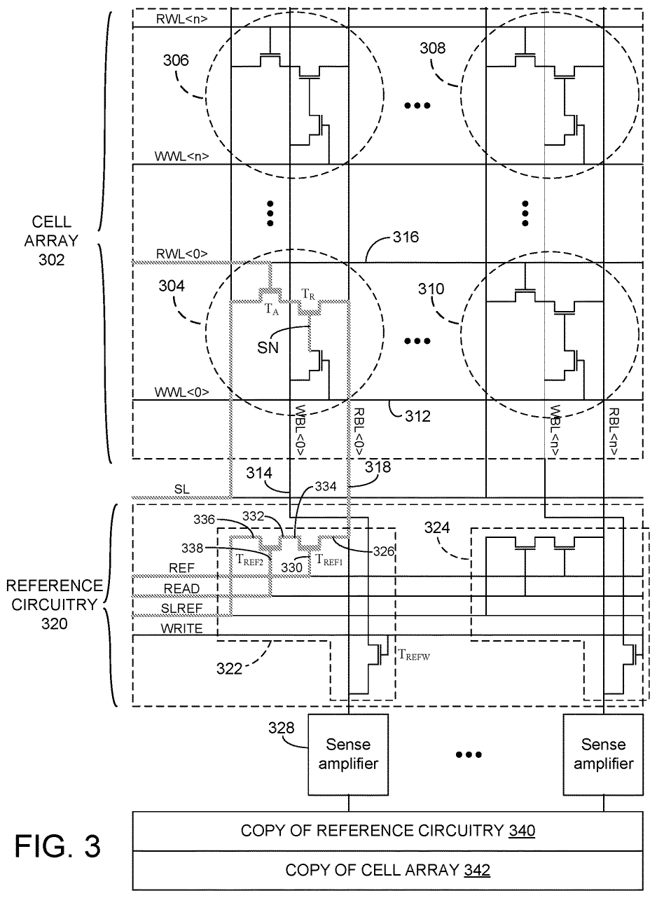

FIG. 3 illustrates further detail for one embodiment of interrelated portions of a 3T0C DRAM cell array 302 and the sensing circuitry 124 of FIG. 1. The 3T0C DRAM cell array 302 includes multiple 3T0C storage cells, such as at 304, 306, 308 and 310 that are formed similar to the cell structure shown in FIGS. 2A and 2B. Each cell may be activated for a write operation by a unique combined activation of a connected write word line (WWL) and write bit line (WBL), such as those shown at 312 and 314, respectively. Each cell may be activated for a read operation by a unique combined activation of a connected read word line (RWL) and read bit line (RBL), such as those shown at 316 and 318.

Further referring to FIG. 3, for one embodiment, the memory array 120 (FIG. 1) includes reference circuitry 320 formed as a row or stripe of reference cells, such as at 322 and 324. Each reference cell is formed similar to each of the 3T0C cells of the cell array 302, with a pair of series-coupled reference transistors T_{REF1} and T_{REF2}. The first reference transistor T_{REF1} includes a source terminal at 326 that is coupled to the read bit line RBL 318. The read bit line RBL 318 forms a conductive path between a first sense amplifier 328 and the first 3T0C DRAM cell 304. The first reference transistor T_{REF1} includes a gate terminal 330 that receives a reference voltage REF. The reference voltage REF serves as a bias voltage to serve a purpose similar to the charge stored on the storage node SN of the 3T0C cell 304. The second reference transistor T_{REF2} includes a second source terminal 332 that is coupled to a first drain terminal 334 of the first reference transistor T_{REF1}, and a second drain terminal 336 that is coupled to a source line reference (SLREF) voltage. A gate terminal 338 of the second reference transistor T_{REF2} receives a read READ voltage that serves as an equivalent voltage to the read word line RWL voltage applied to the gate of the access transistor T_{A} of the 3T0C cell 304. For some embodiments, each reference cell includes a reference write transistor T_{REFW} that serves as a switch to connect each sense amplifier, such as at 328, to each write bit line WBL, such as at 314. When the reference write transistor T_{REF2} is off, the sense amplifier 328 is isolated from the write bit line WBL 314.

For one embodiment, and further referring to FIG. 3, the sense amplifier 328 operates in an open bit line configuration with two relatively balanced loads—a first load formed by the cooperative circuitry of the cell array 302 and the reference circuitry 320, and a second load formed by a copy or second instance of a reference circuit 340 that is similar to the reference circuit 320, and a copy or second instance of a cell array 342 that is similar to the cell array 302. In a read access to cell array 302, one of the read wordlines of cell array 302, e.g., read wordline 316, is activated. No read wordline is activated in copy of cell array 342, thereby providing a balanced load but no signal from cell array 342.

In operation, for a given 3T0C storage cell, such as at 304, a read operation begins by precharging the read bitlines, such as at 318, to a mid-level voltage that is approximately half the full-swing voltage of the array. Row (wordline) and column (bitline) address information received by the cell array 302 results in a voltage applied to read word line 316. At the same time, a source line voltage of e.g., 1V is applied to a source line SL that couples to the source terminal of the access transistor T_{A} for the storage cell 304. The read bit line 318 establishes a node between the storage cell 304, the reference cell 322, and the sense amplifier 328. While the storage cell 304 is being activated, the reference voltage REF and the read voltage READ are applied to the gates 330 and 338 of the two reference cell transistors T_{REF1} and T_{REF2} of the reference cell 322. The source line reference voltage, such as 0V, is also applied to the drain 336 of the second reference transistor T_{REF2}.

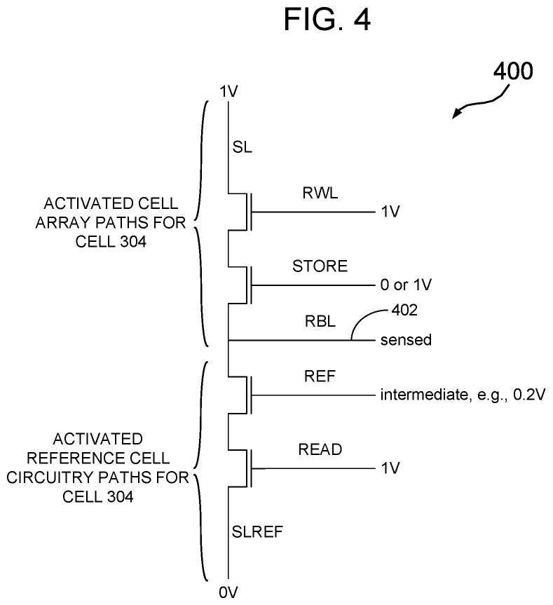

The resulting current path coupled to storage cell 304 formed by the various activations described above forms a resistive voltage divider circuit 400 that is shown in FIG. 4. The voltage divider circuit 400 generally develops a voltage for sensing by the sense amplifier 328 during a signal development phase of the read operation. The top half of the voltage divider 400 is formed by the activated paths of the cell array 302 for storage cell 304, including the series-coupled access and read transistors T_{A} and T_{R}. The center of the voltage divider, at 402, represents the voltage output sensed by the sense amplifier 328 along the read bit line 318. The lower half of the voltage divider 400 is formed by the activated paths of the reference cell circuitry 320. If the charge stored on the storage node SN represents a logic “1”, then the voltage output developed by the voltage divider 400 along the read bit line 318 is slightly above a mid-level voltage. If the charge stored on the storage node SN represents a logic “0”, then the voltage developed by the voltage divider 400 is slightly below the mid-level voltage.

For some embodiments, and with continued reference to FIG. 4, the reference voltage REF may be adjustable in order to correspondingly change the resistive characteristics of the voltage divider 400. In some instances, it may be desirable to configure the reference voltage REF such that when the read transistor T_{R} of the storage cell cell is “on” during the read operation (with the storage node state being high), most of the voltage drop of the voltage divider 400 takes place in the reference circuitry half of the circuit. When the read transistor T_{R} of the storage cell cell is “off” during the read operation (with the storage node state being low), it may be desirable for most of the voltage drop of the voltage divider 400 to take place in the cell array half of the circuit. Thus, choosing an appropriate value for the reference voltage results in an offset slightly above/below a midlevel voltage depending on whether the stored bit on the storage node SN represents a logic 0 or logic 1.

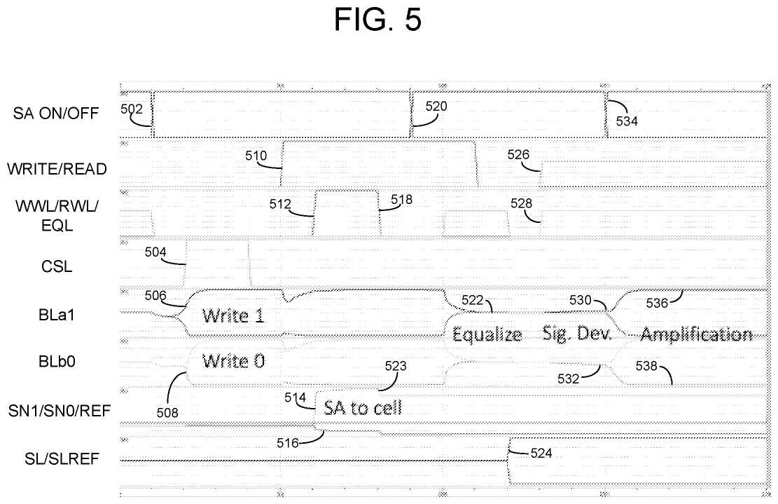

FIG. 5 illustrates relative timing parameters for a set of write and read operations involving alternative storage node states (logic “1” and “0”) carried out for a given 3T0C storage cell in the capacitorless DRAM architecture of FIG. 3. The top four lines of the timing diagram, at 502, 504, 506 and 508, represent timings of control signals to configure the cell array circuitry and reference circuitry for a write operation or read operation. The top line 302 illustrates a Sense Amp On/Off waveform to activate/deactivate a given sense amplifier. The Write/Read line 304 illustrates when a Write control signal or a Read control signal is asserted for the reference circuitry. The third line 306 shows the timings for respective write word line WWL, read word line RWL and equalize EQL control signals for the cell array circuitry. A column select line CSL 308 is also provided to show when a column select line signal is asserted relative to the other control signals.

For a write operation, and further referring to FIG. 5, a given sense amplifier corresponding to the column address information for the write operation is activated by the SA On/Off signal, at 502. The column select signal CSL for bitlines of a given addressed column is asserted, at 504, with the corresponding bit line going high, at 506, for a voltage corresponding to a logic “1”, or low, at 508, for a voltage corresponding to a logic “0.” At 510, a Write signal is asserted for application to a corresponding reference circuitry cell, with a write word line WWL signal applied to the storage cell, at 512, shortly thereafter. With the write word line WWL being asserted, the storage node SN of the storage cell write transistor Tw becomes charged to either a high level, at 514, for a logic “1”, or a low level, at 516, for a logic “0.” The write word line is then deasserted, at 518, followed by the sense amplifier turning off, at 520. The bit line then equalizes to a mid-level voltage, at 522, until the storage node is ready to be accessed for a read operation.

For some embodiments, and further referring to FIG. 5, the storage node for each storage cell may be configured to exhibit an overall capacitance that is larger than a parasitic capacitance to the write word line WWL. This parameter reduces the magnitude of any voltage drop occurring when the write word line WWL is closed, such as the drop shown at 523.

With continued reference to FIG. 5, for a read operation, the cell array circuitry and the reference circuitry goes through a dual phase process that involves a signal development phase and an amplification phase. With the cell array circuitry and reference circuitry in an equalized state, such as at 522, various control signals are received to configure the cell array circuitry and the reference circuitry to form the voltage divider circuit described and shown in FIG. 4. At 524, a sense line SL signal initiates the read configuration, followed shortly thereafter by assertion of a Read control signal, at 526, and a read word line signal, at 528. With the voltage divider circuit fully configured, the voltage divider output develops either a voltage signal slightly higher than a mid-level voltage, such as at 530, resulting from the storage node storing charge corresponding to a logic “1”, or a voltage signal slightly lower than the mid-level voltage, such as at 532, resulting from the storage node storing charge corresponding to a logic “0.” Once the signal offset is developed by the voltage divider circuit, the signal development phase ends, and the amplification phase begins with the sense amplifier turning on, at 534, to amplify the developed signal to a full-swing voltage level representing a read data bit, such as at 536 (for a logic “1”) or 538 (for a logic “0”).

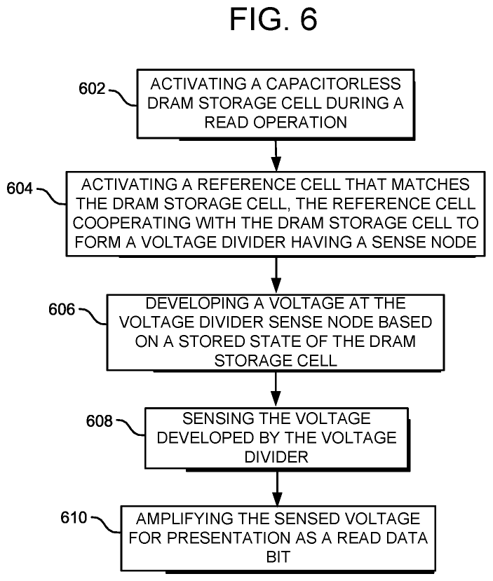

FIG. 6 illustrates steps involved in reading a capacitorless DRAM cell consistent with the description associated with the waveform timing diagrams of FIG. 5. At 602, a capacitorless DRAM storage cell is activated during a read operation. A reference cell is then activated, at 604, that matches the capacitorless DRAM storage cell. The reference cell cooperates with the capacitorless DRAM storage cell to form a voltage divider that includes a sense node. At 606, the voltage divider develops a voltage at the sense node based on a stored state of the capacitorless DRAM storage cell. The developed voltage is then sensed, at 608, by a sense amplifier, and then amplified by the sense amplifier, at 610, as a read data bit.

Those skilled in the art will appreciate the relatively straightforward sensing circuitry for the capacitorless DRAM architecture described above. By employing reference circuitry that cooperates with cell array circuitry to form a voltage divider circuit during a signal development phase of operation, traditional sense amplifiers may be employed in the DRAM sensing circuitry. As a result, improved DRAM storage cell arrays may be employed for improved node scaling without costly redevelopment of complex sensing circuits and techniques.

When received within a computer system via one or more computer-readable media, such data and/or instruction-based expressions of the above described circuits may be processed by a processing entity (e.g., one or more processors) within the computer system in conjunction with execution of one or more other computer programs including, without limitation, net-list generation programs, place and route programs and the like, to generate a representation or image of a physical manifestation of such circuits. Such representation or image may thereafter be used in device fabrication, for example, by enabling generation of one or more masks that are used to form various components of the circuits in a device fabrication process.

In the foregoing description and in the accompanying drawings, specific terminology and drawing symbols have been set forth to provide a thorough understanding of the present invention. In some instances, the terminology and symbols may imply specific details that are not required to practice the invention. For example, any of the specific numbers of bits, signal path widths, signaling or operating frequencies, component circuits or devices and the like may be different from those described above in alternative embodiments. Also, the interconnection between circuit elements or circuit blocks shown or described as multi-conductor signal links may alternatively be single-conductor signal links, and single conductor signal links may alternatively be multi-conductor signal links. Signals and signaling paths shown or described as being single-ended may also be differential, and vice-versa. Similarly, signals described or depicted as having active-high or active-low logic levels may have opposite logic levels in alternative embodiments. Component circuitry within integrated circuit devices may be implemented using metal oxide semiconductor (MOS) technology, bipolar technology or any other technology in which logical and analog circuits may be implemented. With respect to terminology, a signal is said to be “asserted” when the signal is driven to a low or high logic state (or charged to a high logic state or discharged to a low logic state) to indicate a particular condition. Conversely, a signal is said to be “deasserted” to indicate that the signal is driven (or charged or discharged) to a state other than the asserted state (including a high or low logic state, or the floating state that may occur when the signal driving circuit is transitioned to a high impedance condition, such as an open drain or open collector condition). A signal driving circuit is said to “output” a signal to a signal receiving circuit when the signal driving circuit asserts (or deasserts, if explicitly stated or indicated by context) the signal on a signal line coupled between the signal driving and signal receiving circuits. A signal line is said to be “activated” when a signal is asserted on the signal line, and “deactivated” when the signal is deasserted. Additionally, the prefix symbol “/” attached to signal names indicates that the signal is an active low signal (i.e., the asserted state is a logic low state). A line over a signal name (e.g., ‘<̅s̅i̅g̅n̅a̅l̅ n̅a̅m̅e̅>̅’) is also used to indicate an active low signal. The term “coupled” is used herein to express a direct connection as well as a connection through one or more intervening circuits or structures. Integrated circuit device “programming” may include, for example and without limitation, loading a control value into a register or other storage circuit within the device in response to a host instruction and thus controlling an operational aspect of the device, establishing a device configuration or controlling an operational aspect of the device through a one-time programming operation (e.g., blowing fuses within a configuration circuit during device production), and/or connecting one or more selected pins or other contact structures of the device to reference voltage lines (also referred to as strapping) to establish a particular device configuration or operation aspect of the device. The term “exemplary” is used to express an example, not a preference or requirement.

While the invention has been described with reference to specific embodiments thereof, it will be evident that various modifications and changes may be made thereto without departing from the broader spirit and scope of the invention. For example, features or aspects of any of the embodiments may be applied, at least where practicable, in combination with any other of the embodiments or in place of counterpart features or aspects thereof. Accordingly, the specification and drawings are to be regarded in an illustrative rather than a restrictive sense.

1. A memory device, comprising:
an array of storage cells, each storage cell coupled to one of multiple bitlines and one of multiple wordlines;
reference cell circuitry including reference cells, each reference cell coupled to a separate one of the multiple bitlines;
wherein for a given storage cell activated during a read operation by a given wordline and bitline, a corresponding reference cell is coupled to the given bitline and cooperates with the given storage cell to form a voltage divider circuit having a sense node; and
sense amplifier circuitry, during the read operation, to sense a stored state of the given storage cell based on a voltage developed by the voltage divider circuit at the sense node.

2. The memory device of claim 1, wherein:
the array of storage cells comprises an array of capacitorless dynamic random access memory (DRAM) storage cells; and
wherein each capacitorless DRAM storage cell includes a first pair of series-coupled transistors that are activated by the given one of the multiple wordlines and the given one of the multiple bitlines.

3. The memory device of claim 2, wherein each DRAM storage cell further comprises:
a write transistor coupled to the first pair of transistors, the write transistor being activated during a write operation.

4. The memory device of claim 3, wherein the write transistor further comprises:
a gate terminal that is coupled to a write wordline of the array, the write wordline exhibiting a parasitic capacitance; and
wherein the storage node maintains the stored state of the DRAM storage cell with an exhibited capacitance that is larger than the parasitic capacitance of the write wordline.

5. The memory device of claim 2, wherein the first pair of series-coupled transistors further comprises:
a first transistor having a first gate terminal to receive a read wordline (RWL) signal;
a second transistor serially-coupled to the first transistor and including a second gate terminal to store the state of the storage cell.

6. The memory device of claim 5, wherein:
the state of the storage cell represents a logic one or a logic zero.

7. The memory device of claim 2, wherein each reference cell further comprises:
a second pair of series-coupled transistors configured to match the first pair of series-coupled transistors, the second pair of series-coupled transistors including
a third transistor having a source terminal coupled to a drain terminal of the second transistor to form the sense node, the third transistor having a third gate terminal to receive a reference voltage; and
a fourth transistor serially-coupled to the third transistor and having a fourth gate terminal to receive a reference read wordline voltage.

8. The memory device of claim 1, wherein:
a given subset of the array of storage cells that are coupled to a given bitline are written in parallel during a given write operation.

9. The memory device of claim 1, wherein:
the given storage cell and the corresponding reference cell that are activated during the read operation are to develop a first voltage above a mid-level voltage on the sense node when the stored state is of a first value, and to develop a second voltage below the mid-level voltage on the sense node when the stored state is of a second value that is different from the first value.

10. The memory device of claim 1, wherein:
the sense amplifier circuitry, during an amplification phase of the read operation, amplifies a difference between the developed first voltage or second voltage and the mid-level voltage to a full-swing voltage representing a bit of read data.

11. A dynamic random access memory (DRAM) integrated circuit (IC) memory chip, comprising:
an array of capacitorless DRAM storage cells, each capacitorless DRAM storage cell coupled to one of multiple bitlines and one of multiple wordlines, each capacitorless DRAM storage cell including a first pair of series-coupled transistors that are activated during a read operation;
reference cell circuitry including reference cells, each reference cell coupled to a separate one of the multiple bitlines;
wherein for a given capacitorless DRAM storage cell activated during a read operation by a given wordline and bitline, a corresponding reference cell is coupled to the given bitline and cooperates with the given capacitorless DRAM storage cell to form a voltage divider circuit having a sense node; and
sense amplifier circuitry, during the read operation, to sense a stored state of the given capacitorless DRAM storage cell based on a voltage developed by the voltage divider circuit at the sense node.

12. The DRAM IC memory chip of claim 11, wherein the first pair of series-coupled transistors further comprises:
a first transistor having a first gate terminal to receive a read wordline (RWL) signal; and
a second transistor serially-coupled to the first transistor and including a second gate terminal to store the state of the given capacitorless DRAM storage cell.

13. The DRAM IC memory chip of claim 11, wherein each reference cell further comprises:
a second pair of series-coupled transistors configured to match the first pair of series-coupled transistors, the second pair of series-coupled transistors including
a third transistor having a source terminal coupled to a drain terminal of the second transistor to form the sense node, the third transistor having a third gate terminal to receive a reference voltage; and
a fourth transistor serially-coupled to the third transistor and having a fourth gate terminal to receive a reference read wordline voltage.

14. The DRAM IC memory chip of claim 11, wherein each capacitorless DRAM storage cell further comprises:
a write transistor coupled to the first pair of transistors, the write transistor being activated during a write operation.

15. The DRAM IC memory chip of claim 14, wherein the write transistor further comprises:
a gate terminal that is coupled to a write wordline of the array, the write wordline exhibiting a parasitic capacitance; and
wherein the storage node maintains the stored state of the given capacitorless DRAM storage cell with an exhibited capacitance that is larger than the parasitic capacitance of the write wordline.

16. The DRAM IC memory chip of claim 11, wherein:
a given subset of the array of capacitorless DRAM storage cells that are coupled to a given bitline are written in parallel during a given write operation.

17. The DRAM IC memory chip of claim 11, wherein:
the given capacitorless DRAM storage cell and the corresponding reference cell that are activated during the read operation are to develop a first voltage above a mid-level voltage on the sense node when the stored state is of a first value, and to develop a second voltage below the mid-level voltage on the sense node when the stored state is of a second value that is different from the first value.

18. The DRAM IC memory chip of claim 11, wherein:
the sense amplifier circuitry, during an amplification phase of the read operation, amplifies a difference between the developed first voltage or second voltage and the mid-level voltage to a full-swing voltage representing a bit of read data.

19. A method of operating a memory device, the method comprising:
activating a capacitorless dynamic random access memory (DRAM) storage cell during a read operation;
activating a reference cell that matches the capacitorless DRAM storage cell, the reference cell cooperating with the DRAM storage cell to form a voltage divider having a sense node;
developing a voltage at the voltage divider sense node based on a stored state of the capacitorless DRAM storage cell;
sensing the voltage developed by the voltage divider circuit; and
amplifying the sensed voltage for presentation as a read data bit.

20. The method of claim 19, wherein the developing of the voltage further comprises:
generating a first voltage above a mid-level voltage on the sense node when the stored state is of a first value; and
generating a second voltage below the mid-level voltage on the sense node when the stored state is of a second value that is different from the first value.
